(19) United States
(12) Patent Application Publication
(10) Pub. No.: US 2004/0188835 A1
(43) Pub. Date: Sep. 30, 2004

(54) Semiconductor device having wiring layer

(75) Inventor: Masahiro Owada, Oita-shi (JP)

Correspondence Address: FOLEY AND LARDNER, SUITE 500, 3000 K STREET NW, WASHINGTON, DC, 20007, US

(73) Assignee: KABUSHIKI KAISHA TOSHIBA

(21) Appl. No.: 10/734,656

(22) Filed: Dec. 15, 2003

(30) Foreign Application Priority Data
Mar. 28, 2003 (JP) 2003-091973

(51) Int. Cl. H01L 23/48

(52) U.S. Cl. 257/737

(57) ABSTRACT

A semiconductor device is formed of a wiring layer having a plurality of divided wirings, and a plurality of non-wiring layers. The plurality of the divided wirings extend in a predetermined direction. The plurality of the divided wirings are divided from each other in a direction perpendicular to the extending direction. The wiring layer is formed of a plurality of grains and formed on a semiconductor substrate. Each of the divided wirings has a width smaller than the size of the grains forming the wiring layer. Each of the plurality of the non-wiring layers is formed between the plurality of the divided wirings of the wiring layer. The non-wiring layers extend in the direction in which the plurality of divided wirings extend.

### CROSS-REFERENCE TO RELATED APPLICATIONS

This application is based upon and claims the benefit of priority from the prior Japanese Patent Application No. 2003-091973, filed Mar. 28, 2003, the entire contents of which are incorporated herein by reference.

### BACKGROUND OF THE INVENTION

1. Field of the Invention

This invention relates to a semiconductor device having a wiring layer.

2. Description of the Related Art

In conventional semiconductor devices, a wiring layer formed of a metal film and the like is used. FIG. 1 shows a top view of a conventional wiring layer. A wiring layer 102 made of metal is formed on a semiconductor substrate 101.

In the structure of the wiring layer shown in FIG. 1, if a void 103 is generated in the wiring layer 102 by electromigration, a cross section of a part of the wiring layer having the void is reduced by the void. Therefore, a current density of the part locally increases, which promotes growth of the void 103. If the void 103 has grown to extend to the whole width of the wiring layer 102, disconnection occurs, which causes malfunction of semiconductor devices (such as an LSI).

Further, as another structure of a wiring layer, in a wiring layer having a large grain size and provided with slits in its main portion to ease stress due to stress migration, a structure has been proposed wherein buried layers having a small grain size are provided in side surfaces and slits of the wiring layer (please refer to Jpn. Pat. Appln. KOKAI Pub. No. 5-275426 (FIG. 5)).

However, although the structure shown in the above document can reduce stress, it cannot inhibit a void generated in a wiring layer due to electromigration from extending in a width direction of the wiring layer.

### BRIEF SUMMARY OF THE INVENTION

According to one aspect of the present invention, a semiconductor device of the present invention comprises: a wiring layer having a plurality of divided wirings extending in a predetermined direction, the plurality of divided wirings being divided from each other in a direction perpendicular to the extending direction, the wiring layer being formed of a plurality of grains, the divided wirings each having a width smaller than a size of the grains forming the wiring layer, the wiring layer being formed on a semiconductor substrate; and a plurality of slit-shaped non-wiring layers, each of which is formed between the plurality of divided wirings of the wiring layer, the non-wiring layers extending in the extending direction of the plurality of the divided wirings.

According to another aspect of the present invention, a semiconductor device of the present invention comprises: a first insulating film formed on a semiconductor substrate; a wiring layer having a plurality of divided wirings extending in a first direction, the wiring layer being formed of a plurality of grains and formed on the first insulating film; and a plurality of slit-shaped second insulating films formed at predetermined intervals in a second direction perpendicular to the first direction, and each of the plurality of second insulating films being arranged between the plurality of divided wirings of the wiring layer, and extending in the first direction. Each of the plurality of the divided wirings has a width smaller than a size of the grains forming the wiring layer.

### BRIEF DESCRIPTION OF THE SEVERAL VIEWS OF THE DRAWING

FIG. 1 is a top view of a conventional wiring layer.

FIG. 2 is a top view showing a structure of a wiring layer which a semiconductor device of an embodiment of the present invention has.

FIG. 3 is a cross-sectional view taken along line 3-3 in the wiring layer of the embodiment.

FIG. 4 is a cross-sectional view showing a first step in a method of manufacturing the semiconductor device of the embodiment.

FIG. 5 is a cross-sectional view showing a second step in the method of manufacturing the semiconductor device of the embodiment.

FIG. 6 is a cross-sectional view showing a third step in the method of manufacturing the semiconductor device of the embodiment.

FIG. 7 is a cross-sectional view showing a fourth step in the method of manufacturing the semiconductor device of the embodiment.

FIG. 8 is a top view showing a structure of grains existing in a conventional wiring layer.

FIG. 9 is a top view showing a structure of grains existing in the wiring layer of the embodiment.

FIG. 10 is a diagram showing relativity of a wiring life to wiring width in the semiconductor device of the embodiment.

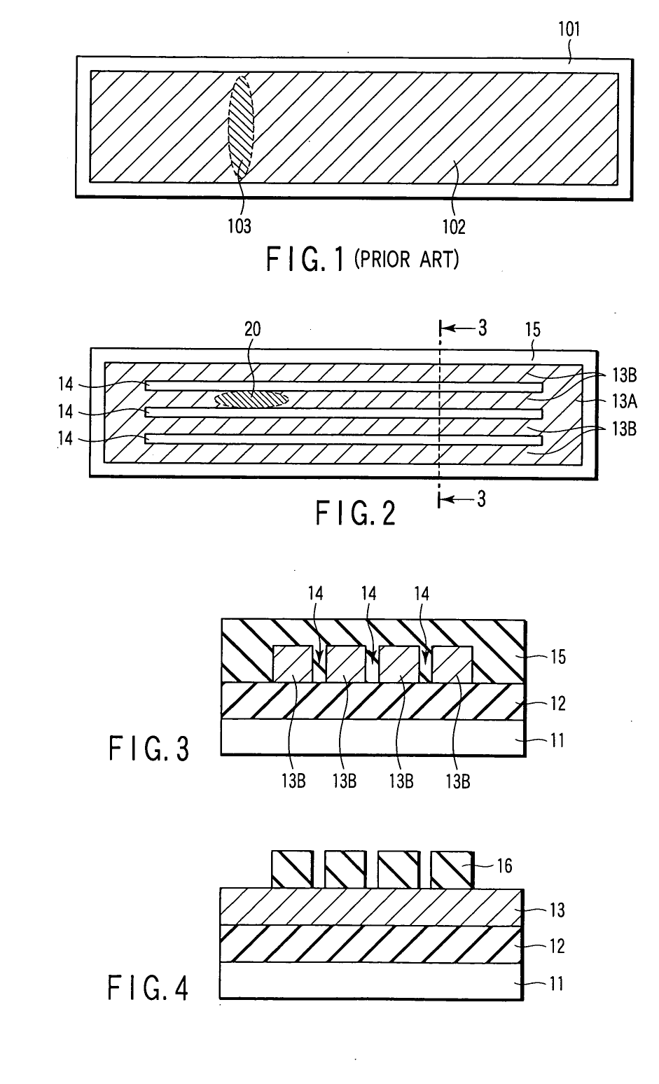

### DETAILED DESCRIPTION OF THE INVENTION

A semiconductor device of an embodiment of the present invention will now be described with reference to the drawings. In explanation, like reference numerals denote like constituent elements throughout the drawings.

FIG. 2 is a top view showing a structure of a wiring layer which a semiconductor device of the embodiment of the present invention has. FIG. 3 is a cross-sectional view of the wiring layer taken along line 2-2 in the wiring layer.

As shown in the drawings, a wiring layer 13A is formed on a lower insulating film 12 on a semiconductor substrate 11. In the wiring layer 13A, a plurality of slit-shaped non-wiring layers 14 running in a longitudinal direction (extending direction) of the wiring layer 13A are provided, at predetermined intervals, in parallel to the longitudinal direction of the wiring layer 13A. The non-wiring layers 14 is formed of, for example, an insulating film 15, such as an oxide film. The wiring layer 13A is divided into a plurality of divided wirings 13B by the non-wiring layers 14.

The wiring layer 13A and the divided wirings 13B are formed of a metallic material, such as aluminum (Al), copper (Cu), or an alloy mainly containing aluminum (i.e. alloy made by adding 1% or less of copper to aluminum). The wiring layer 13A has a wiring width which is sufficiently wider than a minimum wiring width of its design rules (i.e. a width at least 10 times the minimum wiring width). Further, the width of each of the divided wirings 13B divided by the non-wiring layers 14 is set to be smaller than an average grain size of the material forming the wiring layer 13A. For example, if the wiring layer 13A is an Al wiring formed of Al and an average grain size in the Al wiring is about 1.5 μm, the width of each divided wiring 13B is set to be smaller than 1.5 μm. The width of a part of the insulating film forming each of the non-wiring layers 14 may be the minimum width processable.

Next, a method of manufacturing a semiconductor device having the wiring layer of the embodiment of the present invention will be described. FIGS. 4 to 7 are cross-sectional views showing steps of a method of manufacturing the semiconductor device of the embodiment.

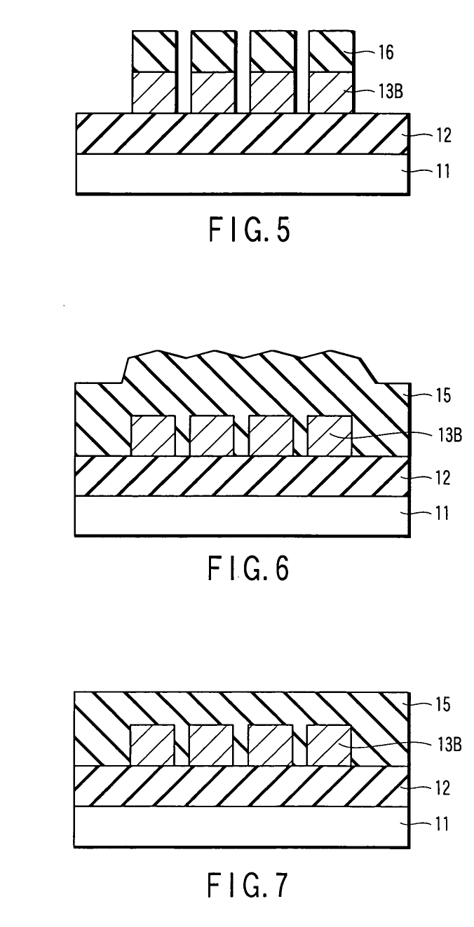

First, as shown in FIG. 4, a lower insulating film 12 is formed on a semiconductor substrate 11, and a metal film 13 to serve as a wiring layer including divided wirings is formed on the lower insulating film 12. Further, a mask material 16, such as a resist film, is patterned on the metal film 13 by photo-lithography. Then, as shown in FIG. 5, the metal film 13 is etched by RIE, forming divided wirings 13B.

Thereafter, the mask material 16 is removed and then, as shown in FIG. 6, an interlayer dielectric 15 is formed on the lower insulating film 12, and also on the divided wirings 13B, thereby the interlayer dielectric 15 is embedded between the divided wirings 13B.

Further, as shown in FIG. 7, the interlayer dielectric 15 is flattened by CMP (Chemical Mechanical Polishing). By the above steps, the semiconductor device having the divided wirings 13B is manufactured.

The following are improvements and effects produced by the semiconductor device of the embodiment.

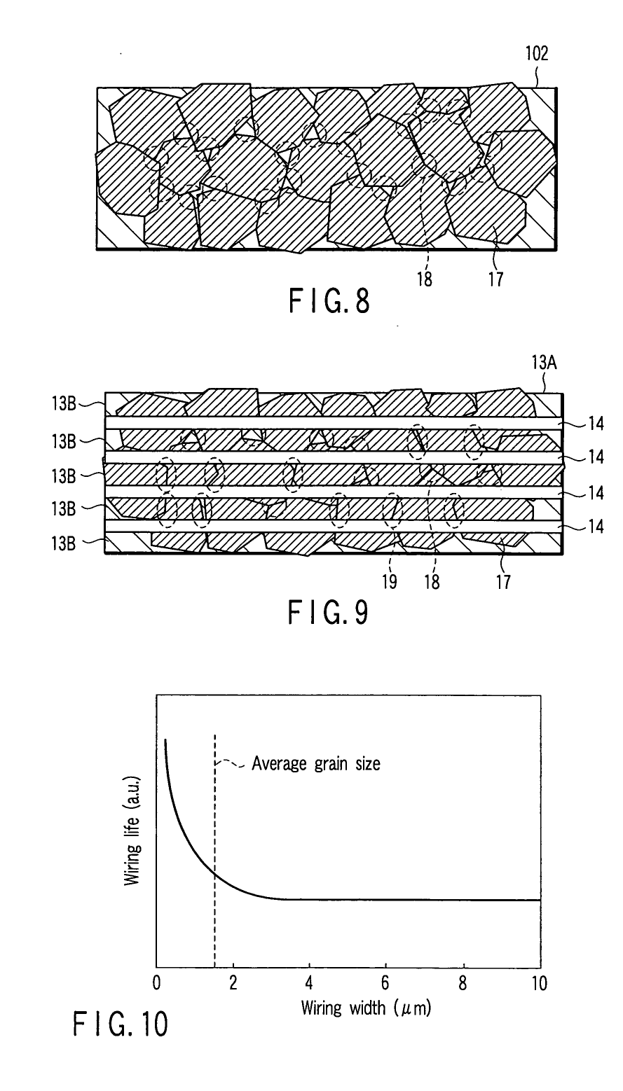

FIG. 8 is a diagram showing the structure of grains existing in a conventional wiring layer 102, that is, wiring layer 102 having no divided wirings. As shown in FIG. 8, a plurality of grains 17 are arranged in the wiring layer 102, and many grain triple points 18, where three grains 17 contact, exist on boundaries between the grains.

The grain triple points 18 are the origins of voids due to electromigration, thus many voids are generated, extending through the whole wiring layer, and this causes an increase in the wiring resistance, and disconnections.

In comparison with this, FIG. 9 shows the structure of grains existing in the wiring layer having the structure shown in FIG. 2. As shown in FIG. 9, if the divided wirings 13B are formed by dividing the wiring layer 13A by non-wiring layers 14, the grains existing in the wiring layer are cut by the slit-shaped non-wiring layers 14, thereby grain triple points are reduced, and instead, bamboo structures (structure like a bamboo joint) 19 having a high resistance to electromigration are generated. This can reduce the number of voids generated, thus can prevent increase in the wiring resistance and disconnection.

Further, the non-wiring layers (for example, insulation film) 14 provided in a longitudinal direction of the wiring layer 13A can prevent a void 20, generated in the divided wiring 13B, from growing in the width direction of the wiring layer 13A, and thereby disconnection occurring in the wiring layer 13A can be reduced.

FIG. 10 shows the relativity of the wiring life to the wiring width in the semiconductor device of the embodiment.

As is clear from FIG. 10, the life of wiring greatly varies around the value of the average grain size. Specifically, the life of wiring increases if the wiring width is smaller than the value of the average grain size, and the life has a low and fixed value if the wiring width is greater than the value of the average grain size.

If the wiring width is smaller than the average grain size, grain triple points are reduced and regions having a bamboo structure become predominant, thus the resistance to electromigration increases. In the meantime, if the wiring width is greater than the average grain size, the wiring layer has many grain triple points, thus the resistance to electromigration decreases. For these reasons, as described above, the wiring life varies greatly around the value of the average grain size.

By providing the non-wiring layers in a longitudinal direction of the wiring layer, it is possible to prevent voids caused by electromigration from growing in the width direction of the wiring layer and prevent disconnection. In addition, as shown in FIG. 10, the life of each divided wiring obtained by dividing the wiring layer increases, thus reliability of the whole wiring layer also increases.

In measurement of the wiring life, the method of accelerated test was adopted, in which a current greater than a normal current is continuously applied to the wiring layer in the state where the wiring layer is heated at. 200 to 300° C. by a temperature bath, and its resistance value is steadily monitored. The time from the start of the test to the point where the resistance value of the wiring layer reaches a certain reference value was defined as the wiring life. A resistance value which has increased by 10-20% from the resistance value of the wiring layer before test was set as the reference value.

As explained above, according to the embodiment, the slit-shaped non-wiring layers (for example, insulating film) are formed in the longitudinal direction (extending direction) of the wiring layer, setting the width of each divided wiring obtained by division of the wiring layer by the non-wiring layers to be smaller than the average grain size, and thereby the number of the triple points existing in the wiring layer is reduced. Thereby, divided wirings each having a bamboo structure are formed, and thereby it is possible to reduce generation of voids caused by electromigration. Further, since the wiring layer is divided into plural divided wirings by the slit-like non-wiring layers, the slits-like non-wiring layers can prevent voids generated by elecromigration from growing in the wiring width direction. Thereby, it is possible to inhibit increase in the resistance of the wiring layer and reduce disconnection, and prevent faults in the semiconductor device.

The above embodiment is not the only embodiment, and various embodiments are possible by changing the above structure or adding various structures.

As described above, according to the above embodiment of the present invention, it is possible to provide a semiconductor device which can reduce generation of voids in the wiring layer and, even if a void is generated, can inhibit the void from growing in the wiring width direction.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a wiring layer having a plurality of divided wirings extending in a predetermined direction, the plurality of divided wirings being divided from each other in a direction perpendicular to the extending direction, the wiring layer being formed of a plurality of grains, the divided wirings each having a width smaller than a size of the grains forming the wiring layer, the wiring layer being formed on a semiconductor substrate; and
a plurality of slit-shaped non-wiring layers, each of which is formed between the plurality of divided wirings of the wiring layer, the non-wiring layers extending in the extending direction of the plurality of the divided wirings.

2. A semiconductor device according to claim 1, the wiring layer having a width which is greater than the size of the grains forming the wiring layer.

3. A semiconductor device according to claim 1, the wiring layer having a width which is greater than a minimum wiring width prescribed by design rules.

4. A semiconductor device according to claim 1, the wiring layer being formed of an alloy mainly containing aluminum.

5. A semiconductor device according to claim 1, the non-wiring layers including an insulating film.

6. A semiconductor device according to claim 1, the width of each of the divided wirings being shorter than 1.5 μm.

7. A semiconductor device comprising:
a first insulating film formed on a semiconductor substrate;
a wiring layer having a plurality of divided wirings extending in a first direction, the wiring layer being formed of a plurality of grains and formed on the first insulating film; and
a plurality of slit-shaped second insulating films formed at predetermined intervals in a second direction perpendicular to the first direction, each of the plurality of second insulating films being arranged between the plurality of divided wirings of the wiring layer, and extending in the first direction,
wherein each of the plurality of the divided wirings has a width smaller than a size of the grains forming the wiring layer.

8. A semiconductor device according to claim 7, the wiring layer having a width which is greater than the size of the grains forming the wiring layer.

9. A semiconductor device according to claim 7, the wiring layer having a width which is greater than a minimum wiring width prescribed by design rules.

10. A semiconductor device according to claim 7, the wiring layer being formed of an alloy mainly containing aluminum.

11. A semiconductor device according to claim 7, the width of each of the divided wirings being shorter than 1.5 μm.
